(19) United States
(12) Patent Application Publication
(10) Pub. No.: US 2022/0078919 A1
(43) Pub. Date: Mar. 10, 2022

(54) PRINTED CIRCUIT BOARDS WITH ELECTRICAL CONTACTS AND SOLDER JOINTS OF HIGHER MELTING TEMPERATURES

(71) Applicant: Hewlett-Packard Development Company, L.P., Spring, TX (US)

(72) Inventor: Roger A. Pearson, Fort Collins, CO (US)

(73) Assignee: Hewlett-Packard Development Company, L.P., Spring, TX (US)

(21) Appl. No.: 17/415,849

(22) PCT Filed: Apr. 15, 2019
(86) PCT No.: PCT/US2019/027536

§ 371 Date: Jun. 18, 2021

(51) Int. Cl. H05K 3/34; H05K 1/14

(52) U.S. Cl. CPC H05K 3/3436; H05K 2203/047; H05K 2201/10325; H05K 1/141

(57) ABSTRACT

A chip may be secured to a first printed circuit board (PCB) via a first solder joint. The first PCB may be secured to a second PCB via a second solder joint. The melting temperature of the first solder joint may be higher than the melting temperature of the second solder joint.

### BACKGROUND

A printed circuit board (PCB) may be used to provide electrical connections between electronic devices. Chips may be soldered to electrical contacts on the PCB, which may couple the chips together to form an electrical circuit.

### BRIEF DESCRIPTION OF THE DRAWINGS

Various examples will be described below referring to the following figures:

FIG. 1 shows an apparatus with a PCB, a chip, and two solder joints in accordance with various examples;

FIG. 2 shows an apparatus with two PCBs, a component, and solder in accordance with various examples;

FIG. 3 shows two PCBs, a processor socket, a processor, and a heating trace in accordance with various examples;

FIG. 4 shows a method of soldering PCBs together in accordance with various examples; and

FIG. 5 shows a method of soldering PCBs together and removing them in accordance with various examples.

### DETAILED DESCRIPTION

Solder may be used to couple components to a PCB. Solder may include various metals that may be melted to form a joint between components. The joint may provide an electrical connection between the components as well as a physical connection and physical stability between the components. There may be multiple solder joints to couple the component to the PCB. Other components may be coupled to the PCB with solder. Removing a specific component from the PCB may involve heating up the solder until it melts, allowing removal of the component. In heating up the solder joints for one component, the solder joints for other components may also be heated to their melting point and come loose or be removed from the PCB. Such loosening or removal may be unintentional.

For a component or groups of components that may be replaced, an additional PCB may be used. The components may be soldered to the additional PCB using a high-temperature solder. The various components of the PCBs may also be soldered using the high-temperature solder. The two PCBs may be soldered together using a low-temperature solder. By heating the solder joints joining the PCBs to a melting temperature of the low-temperature solder, which is below the melting temperature of the high-temperature solder, the PCBs may be separated without melting the high-temperature solder holding the various components to the PCBs. The additional PCB may thereby be replaced with another PCB. This may allow relatively easy modification or repair of electronic devices in the field by a technician.

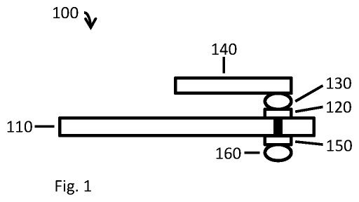

FIG. 1 shows an apparatus 100 with a PCB 110, a chip 140, and two solder joints 130, 160 in accordance with various examples. The PCB 110 may be part of a computer or other electronic device. The PCB 110 includes electrical contacts 120, 150. While the electrical contacts 120, 150 are depicted as jutting out from the PCB 110 (in order to make them more visible), the electrical contacts 120, 150 may be landing pads or traces on the surface of the PCB 110 with minimal rise from the surface of the PCB 110, or may be flush or below the surface of the PCB 110. In various examples, the first electrical contact 120 may be directly opposite the second electrical contact 150, and they may be coupled together, such as with a via in the PCB 110.

The chip 140 is coupled to the PCB 110 via a solder joint 130. The solder joint 130 may couple an electrical contact of the chip 140 with the first electrical contact 120 on the PCB 110. Additional solder joints may be present to couple additional contacts of the chip 140 with the PCB 110.

The PCB 110 may be coupled to a second PCB at the second electrical contact 150 (the second PCB is not depicted in FIG. 1). This coupling may be via a second solder joint 160. The second solder joint 160 may couple the second electrical contact 150 to an electrical contact on the second PCB. An electrical contact on the chip 140 may be coupled to the electrical contact on the second PCB via the first solder joint 130, first electrical contact 120, the PCB 110, such as with a via between the first electrical contact 120 and the second electrical contact 150, the second electrical contact 150, and the second solder joint 160.

The first solder joint 130 may be created using a high-temperature solder. The second solder joint 160 may be created using a low-temperature solder. In various examples, the chip 140 and any other components may be soldered to the PCB 110 using the high-temperature solder. Other components may be soldered to the second PCB using the high-temperature solder. The PCB 110 may be soldered to the second PCB using a low-temperature solder. The low-temperature solder may be heated to its melting point to allow soldering the PCB 110 to the second PCB, but the low-temperature solder may be kept below the melting point of the high-temperature solder, as to not disturb the components that were previously soldered to the PCB 110 or the second PCB. The PCB 110 may be removed from the second PCB by heating the low-temperature solder to its melting point. By keeping the heat below the melting point of the high-temperature solder, the PCB 110 may be removed without disturbing the components previously soldered to the PCB 110 or the second PCB. A third PCB may then be soldered to the second PCB, as to replace the PCB 110.

In various examples, additional chips or other components may be soldered to the PCB 110. Replacement of the PCB 110 may thus effectuate the replacement of multiple components or the replacement of components with different components, such as by a different manufacturer or that perform a different functionality.

In various examples, the PCB 110 may couple the chip 140 or other components soldered to the PCB 110 to corresponding positions on the second PCB. PCB 110 may use vias to couple electrical contacts on one side to directly opposite electrical contacts on the other side. The connection layout for the chip 140 may match the connection layout on the second PCB, with the PCB 110 acting as an intermediate layer that passes signals between the chip 140 and second PCB without rerouting the signals or modifying their layout positions.

In various examples, the connection layouts may match, but be shrunk from one to another, such as when two chips have matching connection layouts, but one is in a smaller form factor. The PCB 110 may expand the form factor from one side of the PCB 110 to the other in order to line up the connection layouts.

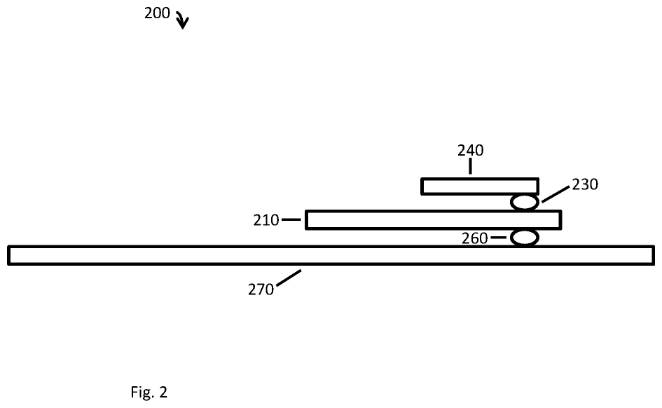

FIG. 2 shows an apparatus 200 with two PCBs 210, 270, a component 240, and solder 230, 260 in accordance with various examples. The first PCB 210 is coupled to the component 240 via the first solder 230. The second PCB 270 is coupled to the first PCB 210 via the second solder 260. The first solder 230 has a higher melting temperature than the second solder 260.

In various examples, the first PCB 210 may be removed from the second PCB 270 by heating the second solder 260 to its melting temperature. By keeping the heat below the higher melting temperature of the first solder 230, the component 240 may remain firmly coupled to the first PCB 210 during the removal. Other components may be soldered to the second PCB 270 via high-temperature solder and also remain firmly coupled to the second PCB 270 during removal of the first PCB 210.

In various examples, the component 240 may be a processor and the second PCB 270 may be a computer motherboard. Coupling the component 240 to the second PCB 270 via the first PCB 210 and solder 230, 260 may allow a more efficient connection between the component 240 and second PCB 270 than use of a processor socket with a mechanical coupling. Using the first PCB 210 and solder 230, 260 may allow for consumption of less power or for faster signals between the component 240 and the second PCB 270. This configuration may allow for additional capacitive decoupling between the ground and power rails, that may result in better power delivery to the processor or use of fewer discrete components.

In various examples, the component 240 may have several pins close together that carry different signals. The first PCB 210 may use several layers to route the appropriate connections to those pins. The number of layers may exceed the number of layers otherwise used by the second PCB 270. By using a first PCB 210 with a higher layer count, the additional cost of those layers may be less than if the component 240 were mounted directly on the second PCB 270 and the second PCB 270 were manufactured with the additional layers.

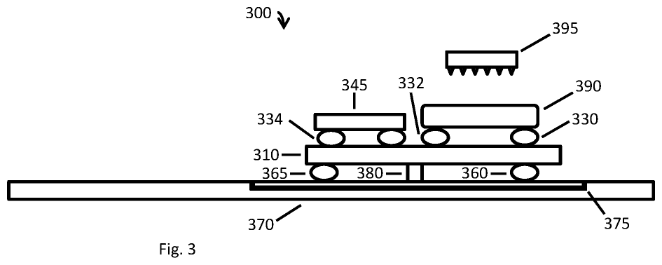

FIG. 3 shows two PCBs 310, 370, a processor socket 390, a processor 395, and a heating trace 375 in accordance with various examples. The first PCB 310 is coupled to the processor socket 390 via high-temperature solder 330, 332. The first PCB 310 is coupled to a second chip 345 via high-temperature solder 334. The first PCB 310 is coupled to the second PCB 370 via low-temperature solder 360, 365. Additional high-temperature solder points may connect the first PCB 310 to the processor socket 390, and second chip 345. Additional low-temperature solder points may connect the first PCB 310 to the second PCB 370.

In various examples, the processor socket 390 may couple the processor 395 to a computer motherboard. The second PCB 370 may be a computer motherboard. The processor 395 may be electrically connected to the second PCB 370 via the processor socket 390, the high-temperature solder 330, 332, the first PCB 310, and the low-temperature solder 360. The processor 395 may couple to the processor socket 390 via a set of land pads, a set of pins and pin receivers, a ball grid array (BGA) and BGA socket, or in another fashion.

In various examples, the second chip 345 may be coupled to the first PCB 310 via the high-temperature solder 334. The second chip 345 may be associated with the processor 395, such as a cache memory, or may operate independently of the processor 395.

In various examples, components may be soldered to the first PCB 310 on the side facing the second PCB 370.

In various examples, a spacer 380 may be used to keep a gap between the first PCB 310 and the second PCB 370. The spacer 380 may keep a gap based on components soldered to the first PCB 310 or second PCB 370 on the facing surfaces. The spacer 380 may keep a gap between the first PCB 310 and second PCB 370 to prevent traces on the surfaces of the PCBs 310, 370 from touching or prevent arcing between the traces.

In various examples, an alignment device could also be used to align the contacts of the first PCB 310 and the second PCB 370. The spacer 380 may be configured to also act as an alignment device. The alignment device may include a physical pin attached to one of the two PCBs 310, 370, which may be coupled to the spacer 380. The alignment device could include holes in the two PCBs 310, 370 to receive pins to assist in alignment.

In various examples, the two PCBs 310, 370 could include holes to accommodate components extending from the surface of the other PCB 310, 370. The components may extend through the holes to reduce the amount of spacing between the two PCBs 310, 370.

In various examples, the second PCB 370 may include a heating trace 375. The heating trace 375 may be routed near the low-temperature solder 360, 365. Application of a voltage to the heating trace 375 may cause the heating trace to heat up the low-temperature solder 360, 365 to a melting temperature, allowing removal of the first PCB 310 from the second PCB 370 without reaching the melting temperature of the high-temperature solder 330, 332, 334.

In various examples, a heating trace may be present on the first PCB 310 to heat up the low-temperature solder 360, 365. A heating trace may be present on one or both of the first PCB 310 and the second PCB 370. When present on both the first PCB 310 and second PCB 370, the two heating traces may heat up overlapping or non-overlapping sets of solder. In various examples the two heating traces may both heat up low-temperature solder 360, 365. In various examples one heating trace may heat up solder 360 and another heating trace on the other PCB 310, 370 may heat up solder 365.

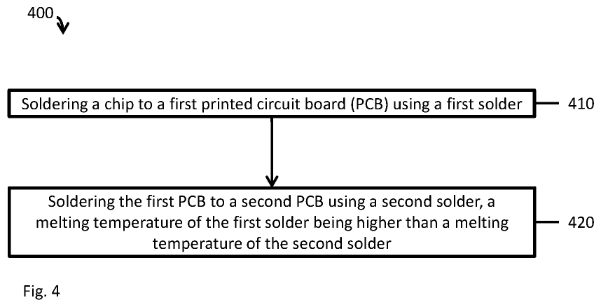

FIG. 4 shows a method 400 of soldering PCBs together in accordance with various examples. Method 400 includes soldering a chip to a first printed circuit board (PCB) using a first solder (410). Method 400 includes soldering the first PCB to a second PCB using a second solder, a melting temperature of the first solder being higher than a melting temperature of the second solder (420).

In various examples, soldering the first PCB to the second PCB may use a heat between the melting temperature of the first solder and the melting temperature of the second solder. This may allow the PCBs to be soldered together without melting the first solder and disturbing the chip soldered to the first PCB. Other components soldered to the first PCB or second PCB with the higher-temperature solder may also be undisturbed.

In various examples, the second solder may be heated to its melting temperature, but below the melting temperature of the first solder. This may allow removing the first PCB from the second PCB without disturbing the chip soldered to the first PCB. Other components soldered to the first PCB or second PCB with the higher-temperature solder may also be undisturbed.

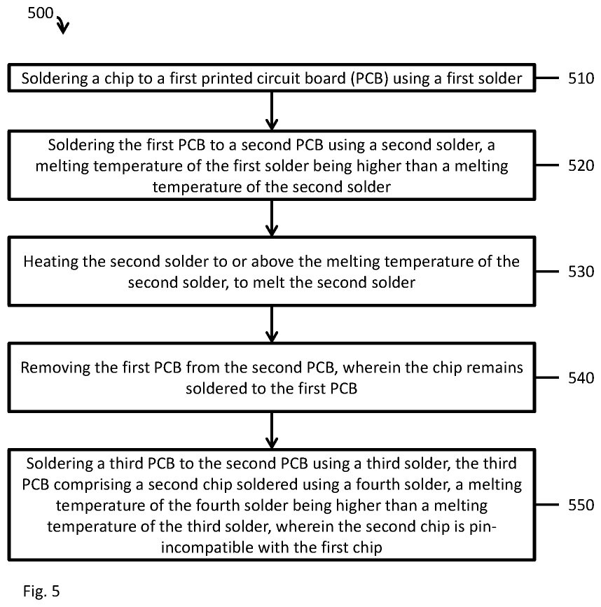

FIG. 5 shows a method 500 of soldering PCBs together and removing them in accordance with various examples. Method 500 includes soldering a chip to a first printed circuit board (PCB) using a first solder (510). Method 500 includes soldering the first PCB to a second PCB using a second solder, a melting temperature of the first solder being higher than a melting temperature of the second solder (520). Method 500 includes heating the second solder to or above the melting temperature of the second solder, to melt the second solder (530). Method 500 includes removing the first PCB from the second PCB, wherein the chip remains soldered to the first PCB (540). Method 500 includes soldering a third PCB to the second PCB using a third solder, the third PCB comprising a second chip soldered using a fourth solder, a melting temperature of the fourth solder being higher than a melting temperature of the third solder, wherein the second chip is pin-incompatible with the first chip (550).

In various examples, different versions of a PCB may be soldered to the second PCB. The different versions of the PCB may implement different specifications. For example, one PCB may include a memory, while a second version of the PCB may include twice as much memory. The two versions of the PCBs may use the same interface to couple to the second PCB and be interchangeably soldered to the second PCB. The second PCB may thus be capable of using the common interface to access the memory of the first version of the PCB or the doubled memory of the second version of the PCB. The PCB versions may include a signal that indicates the PCB version, such as by including a memory that can be queried for a version number or including a specific routing between electrical contacts of the PCB to indicate a PCB version.

In various examples, the different versions of PCBs may include different chips that are pin-incompatible. One version of the PCB may use a chip from one manufacturer, while another version of the PCB may use a different chip from a different manufacturer. The chips may provide comparable functionality but use different pin layouts, such as different locations for power and ground pins or input/output pins. The chips may be from the same manufacturer, but use different form factors or different footprints.

In various examples, the chips may be processors with different interfaces, and the different versions of PCBs may translate the different interfaces into a common interface used by the second PCB. The processors may fit into different processor sockets. Soldering the chip to the first PCB may include soldering the processor socket to the first PCB. The chip may be fitted into the processor socket.

The above discussion is meant to be illustrative of the principles and various examples of the present disclosure. Numerous variations and modifications will become apparent to those skilled in the art once the above disclosure is fully appreciated. It is intended that the following claims be interpreted to embrace all such variations and modifications.

What is claimed is:

1. An apparatus comprising:
a first printed circuit board (PCB);
a first electrical contact on a first surface of the first PCB; and
a second electrical contact on a second surface of the first PCB, the second surface opposite the first surface, the second electrical contact coupled to the first electrical contact;
a first solder joint to secure a chip to the first PCB at the first electrical contact; and
a second solder joint to secure the first PCB to a second PCB at the second electrical contact, wherein a melting temperature of the first solder joint is higher than a melting temperature of the second solder joint.

2. The apparatus of claim 1 comprising a processor socket, the chip secured to the processor socket, and the processor socket secured to the first PCB at the first electrical contact via the first solder joint.

3. The apparatus of claim 1, the first PCB comprising a heater trace to heat the second solder joint to be greater than or equal to the melting temperature of the second solder joint.

4. The apparatus of claim 1, wherein a connection layout of the chip matches a connection layout of the second surface of the first PCB.

5. The apparatus of claim 1, the first PCB comprising a second chip secured to the first PCB via a third solder joint at a third electrical contact on the first surface of the first PCB, wherein a melting temperature of the third solder joint is higher than the melting temperature of the second solder joint.

6. An apparatus comprising:
a first printed circuit board (PCB);
a component soldered to the first PCB via a first solder; and
a second PCB soldered to the first PCB via a second solder, wherein a melting temperature of the first solder is higher than a melting temperature of the second solder.

7. The apparatus of claim 6 comprising a spacer between the first PCB and the second PCB.

8. The apparatus of claim 6, wherein the component includes a socket to receive a chip.

9. The apparatus of claim 6, the second PCB comprising a heater trace to heat the second solder to the melting temperature of the second solder.

10. The apparatus of claim 6, wherein the component includes a processor, and the second PCB includes a motherboard.

11. A method comprising:
soldering a chip to a first printed circuit board (PCB) using a first solder; and
soldering the first PCB to a second PCB using a second solder, a melting temperature of the first solder being higher than a melting temperature of the second solder.

12. The method of claim 11 comprising:
heating the second solder to or above the melting temperature of the second solder, to melt the second solder; and
removing the first PCB from the second PCB, wherein the chip remains soldered to the first PCB.

13. The method of claim 12 comprising soldering a third PCB to the second PCB using a third solder, the third PCB comprising a second chip soldered using a fourth solder, a melting temperature of the fourth solder being higher than a melting temperature of the third solder.

14. The method of claim 13, wherein the second chip is pin-incompatible with the first chip.

15. The method of claim 11, wherein the chip comprises a processor socket, the chip is coupled to the processor socket, and the soldering a chip to the first PCB includes soldering the processor socket to the first PCB.
